(19) United States
(12) Patent Application Publication
(10) Pub. No.: US 2020/0033841 A1
(43) Pub. Date: Jan. 30, 2020

(54) METHODS, APPARATUS AND SYSTEM FOR AUTOMATED RETICLE MOVEMENT FOR SEMICONDUCTOR PROCESSING

(71) Applicant: GLOBALFOUNDRIES INC., Grand Cayman (KY)

(72) Inventors: Sean Calvelli, Ganservoort, NY (US); Christopher Belfi, Mechanicville, NY (US); Anthony Girelli, Wilton, NY (US)

(73) Assignee: GLOBALFOUNDRIES INC., Grand Cayman (KY)

(21) Appl. No.: 16/045,574

(22) Filed: Jul. 25, 2018

(51) Int. Cl. G05B 19/418; G03F 7/20; H01L 21/68

(52) U.S. Cl. CPC G05B 19/4189; H01L 21/682; G03F 7/70741

(57) ABSTRACT

At least one method, apparatus and system disclosed herein involves receiving a reticle and automatically providing the reticle to a semiconductor wafer processing tool. An apparatus of some embodiments herein include a reticle carrier comprising a first slot for receiving the first cassette having loaded within, a first reticle; an identifier detector capable of detecting an identifier associated with the first reticle; an automated handling device capable of automatically receiving the reticle carrier and automatically moving the reticle carrier to a predetermined location; and a reticle handling device capable of extracting the first reticle from the reticle carrier and providing the first reticle to a processing tool.

### BACKGROUND OF THE INVENTION

### Field of the Invention

Generally, the present disclosure relates to the manufacture of sophisticated semiconductor devices, and more specifically, to providing automated movement of reticles for processing semiconductor devices.

### Description of the Related Art

The fabrication of advanced integrated circuits, such as CPU's, storage devices, ASIC' s (application specific integrated circuits) and the like, requires sophisticated processing steps. These processing steps are performed to form a large number of circuit elements in a given chip area according to a specified circuit layout. An example of the these processing steps is a photolithography process. Photolithography processes involve providing light energy to form circuit features on a semiconductor wafer. A masking device, known as reticle, may include various shapes that block the light energy so that desired features are formed on the surface of the semiconductor wafer.

The delivery, transport, usage, and storage of reticles used for processing semiconductor wafers can be very complex. The proper handling of reticles that are delivered into a processing area is important. State of the art handling of reticles are largely performed in a manual fashion, resulting in various inefficiencies. For example, manual handling of reticles may slow process advancement and cause reticle damage. Further, state of the art movement of reticles lack sufficient traceability of the reticles. Often, after performing a photolithography, various process standards call for storing the reticles in close proximity of the process area. Keeping track of the storage of the reticles is generally inefficient using state of the art methodology. Without proper traceability, reticles may become lost and various errors can occur.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus and system for receiving a reticle and automatically providing the reticle to a semiconductor wafer processing tool. An apparatus of some embodiments herein include a reticle carrier comprising a first slot for receiving the first cassette having loaded within, a first reticle; an identifier detector capable of detecting an identifier associated with the first reticle; an automated handling device capable of automatically receiving the reticle carrier and automatically moving the reticle carrier to a predetermined location; and a reticle handling device capable of extracting the first reticle from the reticle carrier and providing the first reticle to a processing tool.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized, block diagram depiction of a system for automated reticle handling, in accordance with some embodiments herein;

FIG. 2 illustrates a stylized, block diagram of the automated reticle handling unit of FIG. 1, in accordance with some embodiments herein;

FIG. 3 illustrates a stylized depiction of a reticle shipping unit of FIG. 2, in accordance with some embodiments herein;

FIG. 4 illustrates a stylized depiction of a cassette that may house a reticle, in accordance with some embodiments herein;

FIG. 5 illustrates a stylized depiction of an adapter for the reticle shipping unit of FIG. 4, in accordance with some embodiments herein;

FIG. 6 illustrates a simplified flowchart depiction of a method in accordance with some embodiments herein; and

FIG. 7 illustrates a more detailed flowchart depiction of a method in accordance with some embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached Figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide an automated reticle handling system that is capable of introducing reticles into a processing area in an automated fashion. One or more reticles may be received, transported, delivered to a processing area, and/or stored, all in substantially an automated fashion. The automated reticle system of embodiments herein may be adapted to track the movements of reticles from delivery into a fab area, routing to a processing tool, storing the reticles for a predetermined time period, and removing the reticle from the processing area, all in a substantially automated manner.

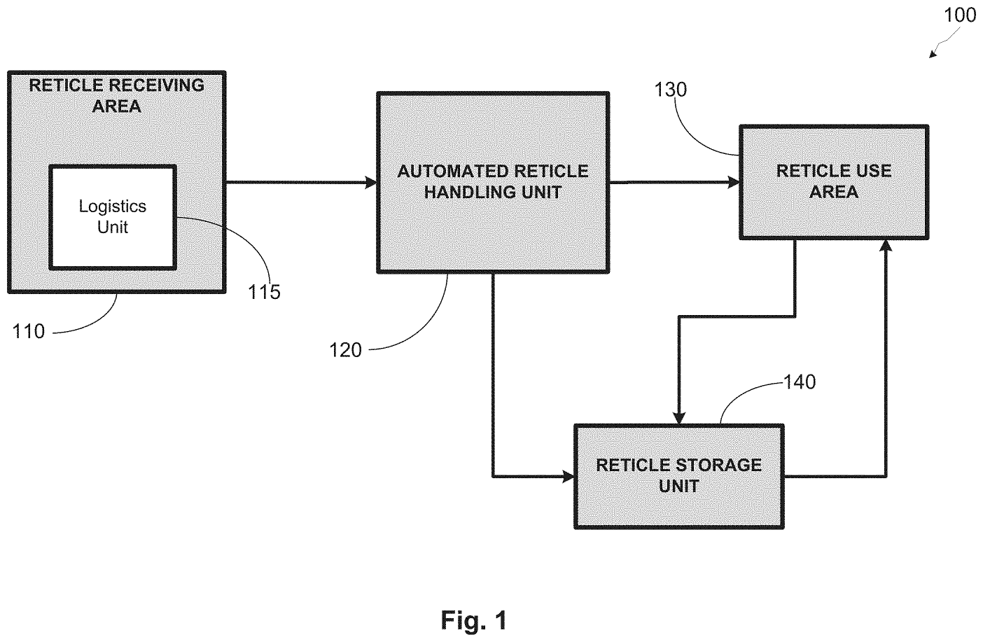

Turning now to FIG. 1, a stylized, block diagram depiction of a system 100 for automated reticle handling, in accordance with embodiments herein, is illustrated. The system 100 is capable of providing tracking and movement control of reticles in a semiconductor wafer manufacturing facility. The system 100 includes a reticle receiving area 110 where reticles are received. The reticle receiving area 100 is generally nearby or within the fab area. In some embodiments, the reticle receiving area 110 may include a receiving dock and a logistics unit 115 that is capable of logging the status of the received reticles and performing initial handling of the reticles. For example, the receiving of the reticles may be logged using a database (e.g., a database offered by Oracle, Corp. The reticles received in the reticle receiving area may be unpacked by a logistics team.

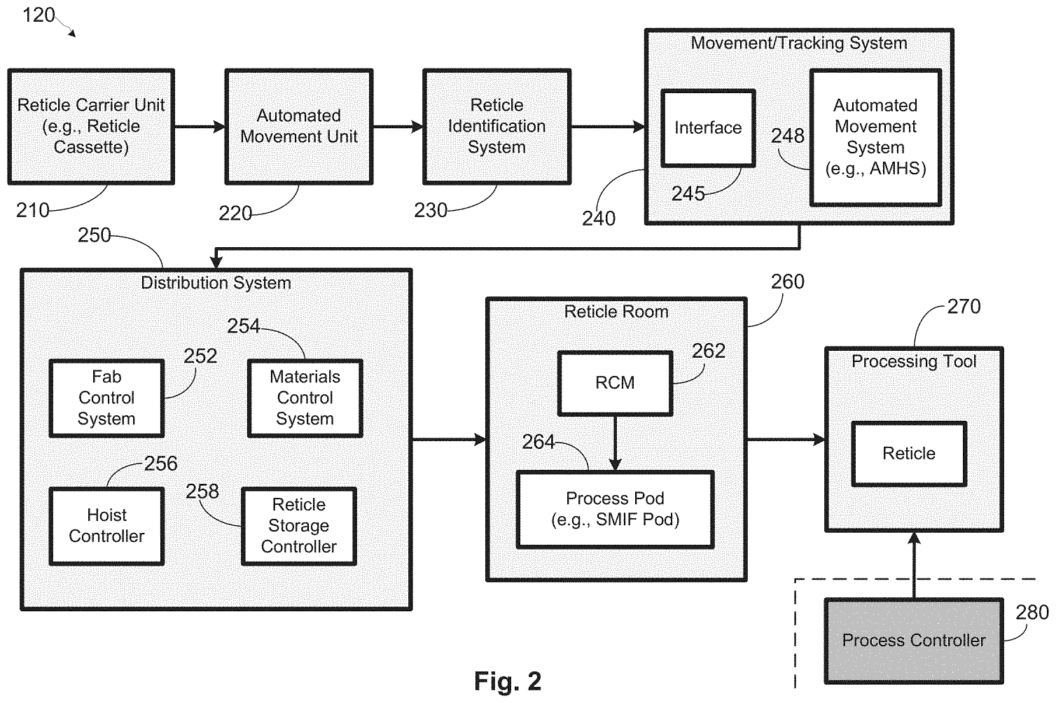

The reticles may be provided to an automated reticle handling unit 120. In one embodiment, the reticles may be automatically loaded onto the automated reticle handling unit 120. In some embodiments, the automated reticle handling unit 120 may be supervised and/or maintained by a Fab services team. The automated reticle handling unit 120 may comprise various components that transport, track, notify, and deliver reticles, as described in further details in FIG. 2 and accompanying description below. In some embodiments, identifiers may be associated with the reticles for tracking the movement and storage of those reticles. The identifiers may be one or more of a plurality of identifiers, such as barcodes, radio frequency identifiers (RFIDs), optical identifiers, and/or any type of identifiers.

In some embodiments, portions of the automated reticle handling unit 120 may be handled, for example, by an Infab Services team, which may stock-out the reticles, load the reticles into a reticle carrier (e.g., reticle cassette), and notify a reticle team. The reticle team may then stock-out the reticle carrier and receives the reticle carrier for Fab use. The reticle team may then prepare for subsequent reception of additional reticles. In other embodiments, these steps may be performed automatically, for example, by software controlled devices, robotics, machine learning devices, etc.

The system 100 may also includes a reticle use area 130, which may include one or more processing tools (e.g., photolithography tools). In some embodiments, the reticles are moved automatically to the reticle use area for Fab use. For example, a predetermined reticle may be identified and routed to a particular photolithography tool for performing a predetermined photolithography process on one or more semiconductor wafers.

The system 100 may also include a reticle storage area 140. Upon use of the reticles, the reticles may be stored in the reticle storage unit 140. The reticle storage unit 140 may be a short-term storage unit and/or a long-term storage unit. In alternative embodiments, the reticle storage unit 140 may be part of the automated reticle handling unit 120. Some semiconductor processing standards may call for storage of the reticles in close proximity to the reticle use area for a predetermined time period. The used reticles may be removed from the Fab area directly from the reticles storage unit 140. Alternatively, the used reticles may be kept in the reticle storage unit 140 and routed to the reticle use area 130 by the automated reticle handling unit 120.

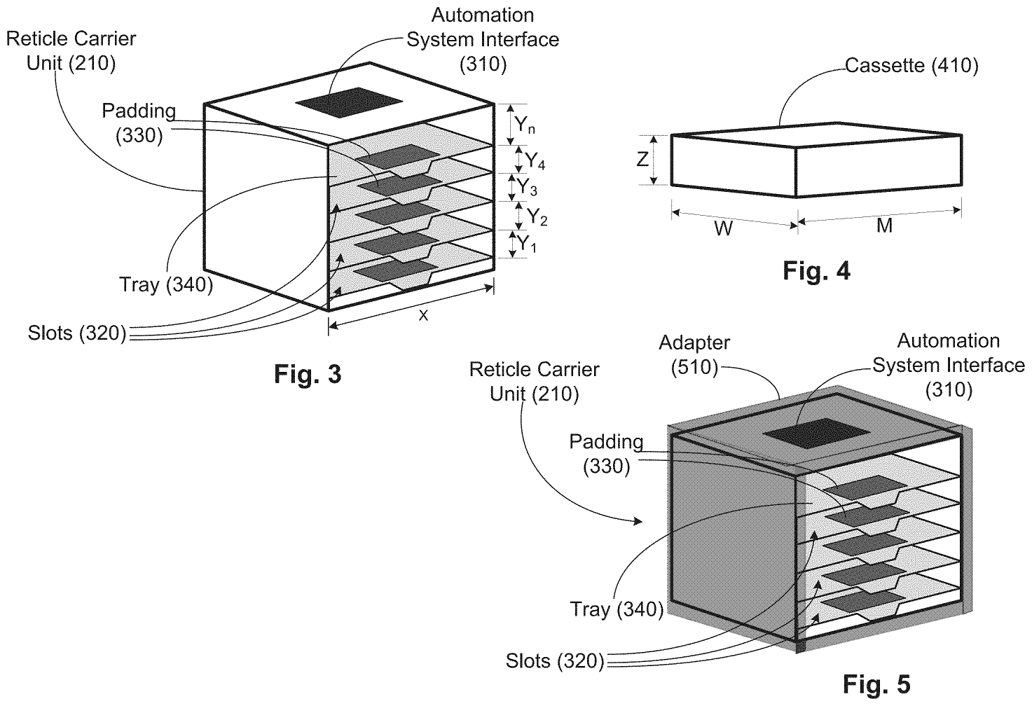

Turning now to FIG. 2, a more detailed, stylized, block diagram of the automated reticle handling unit 120 of FIG. 1, in accordance with some embodiments herein, is illustrated. The automated reticle handling unit 120 includes a reticle carrier unit 210. In one embodiment, the reticle carrier unit 210 may be a reticle cassette, which is described in further details in FIGS. 3 and 4, and accompanying description below. The reticle cassette may be adapted to carry a predetermined number of reticles for a predetermined fab specification, such as 300 nm, 100 nm, 32 nm, 30 nm, 14 nm, 10 nm, 7 nm, 5 nm, etc., wafer-processing specifications. The reticle shipping cassette may arrive at a dock of a fab system and may be unpacked by a logistics team.

The reticle carrier unit 210 may be loaded onto an automated movement unit 220. The automated movement unit 220 may include an automated material handling system (AMHS) that is capable of transporting the reticle carrier unit 210. The automated movement system 220 may comprise various movement devices for transporting the reticle carrier unit 210. For example a front opening universal pod (FOUP)/front opening shipping box (FOSB) (FOUP/FOSB) multi-floor lifter, or a dumb waiter may be used to move the reticle carrier unit 210 from the dock to the fab area.

The automated reticle handling unit 120 may also include a reticle identification system 230. The reticle identification system is capable of identifying the reticle carrier unit 210 and/or the reticles in the reticle carrier unit 210. The reticle identification system 230 is capable of detecting an identification mark on the reticle carrier unit 210 and/or the recites within, storing the associated identification data, reporting the identification data, and tracking the movement of the reticle carrier unit 210 and/or the reticles within. The reticle identification system 230 may include a barcode scanning system, a RFID system, an optical reader system, and/or the like.

The automated reticle handling unit 120 may also include a movement/tracking system 240, which is capable of providing automated movement of the reticle carrier unit 210 and the reticles while maintaining tracking of them. The unit 240 may include an interface 245 that is capable of interfacing with reticle carrier unit 210. The interface 245 may operatively couple to an adapter positioned onto reticle carrier unit 120. The adapter is described further in FIG. 5 and accompanying description below.

The interface 245 provides for operatively coupling the reticle carrier unit 210 to an automated movement system 248 (e.g., an automated vehicle system, “AMHS”). The automated movement system 248 is capable of automatically moving the reticle carrier unit 210 to a distribution system 250 for delivery of the reticles to predetermined, programmed, or prompted locations in the Fab area.

The distribution system 250 may include one or more controllers that are capable of controlling the movement and tracking of reticles to at least one of a Fab processing tool, a materials handling system, a hoist system, and/or a reticle storage system. Accordingly, in some embodiments, the distribution system 250 may include a Fab control system 252, a materials control system 254, a hoist controller 256, and/or a reticle storage controller 258. The various controllers associated with the system 252, 254 and the controllers 256, 258 may be a micro-processor, a computer system, a hand-held device, a software controller, a hardware controller, a firmware controller, and/or any combination thereof.

The Fab control system 252 may control the movement of one or more reticle carrier units 210 and/or individual reticles to and from a predetermined portion of a fab area, e.g., a photolithography processing tool. For example, the fab control system 252 may identify a particular reticle in the reticle carrier unit 210 for usage for a processing step in a particular photolithography tool. In response, the automated movement system 248 may be prompted to move the identified reticle to that photolithography tool.

The materials control system 254 may keep track of each reticle in the reticle carrier unit 210 and control the movements of the reticles throughout the semiconductor manufacturing facility. Various entities in the semiconductor manufacturing facility, such as the fab control system 252, may communicate with the material control system 254 to coordinate the acquisition, delivery, usage, and the extraction of reticles. The material control system 254 may also coordinate storage of the reticles.

The hoist controller 256 is capable of moving the reticle carrier unit 210 onto one or more movement devices, such as the AMHS, and/or to a storage area. The reticle storage controller 258 is capable of extracting reticles used in a fab area and storing the reticles for potential further usage. The reticle storage controller 258 may report the receiving and sending out of reticles to the material control system 254.

Data from the distribution system 250 may be provided to a reticle handling area, often referred to as reticle room 260. The reticle room 260 may include a reticle clean and maintenance (RCM) tool 262 and a process pod 264. The RCM tool 264 in conjunction with the movement/tracking system 240 are capable of transporting the reticle carrier unit 210 to a predetermined portion of the reticle room 260. A predetermined reticle residing in the reticle carrier unit 210 carried by the RCM tool 262 may be extracted automatically or manually, and placed onto the process pod 264. The process pod 264, in one embodiment, may be a standard mechanical interface (SMIF) pod. The radicle may be then delivered to the processing tool 270 (e.g., a photolithography tool) for performing a process.

A process controller 280 may control the operations of the processing tool 270. The process controller 280 may be a workstation computer, a desktop computer, a laptop computer, a tablet computer, or any other type of computing device containing one or more software products that are capable of controlling processes, receiving process feedback, receiving test results data, performing learning cycle adjustments, performing process adjustments, etc. The process controller 280 may be an entity that is separate from the automated reticle handling unit 210.

Upon performing a processing step on a semiconductor wafer using the reticle, the RCM tool 262 and the process pod 264 may be then used to extract the reticle from the processing tool 270. The reticle storage controller 258 may prompt storage of the reticle for a predetermined time period.

Turning now to FIG. 3, a stylized depiction of a reticle carrier unit 210, in accordance with some embodiments herein, is illustrated. The reticle carrier unit 210 may include a plurality of slots 320, wherein one reticle may be arranged into each slot 320. A padding 330 may be arranged into each slot 320 to hold the reticle in place and/or to protect the reticle.

The reticle carrier unit 210 may also include an automation system interface 310. The interface 310 is capable of communicating and interfacing with various portions of the reticle movement system 100. The automation system interface 310 may include communication interface, electronic identifiers, controllers, physical latches, etc., that allow one or more parts of the reticle movement system 100 to transport and track the reticle carrier unit 210.

The reticle carrier unit 210 may include any number of slots, e.g., 1 through n slots (where n is an integer). Each slot 320 includes a tray 340, on which a reticle or a cassette (described below) may be placed. The slots may be formed from a material that is conducive for carrying reticles and/or cassettes. For example, the slots may be formed from common plastic, polyethelene, stainless steel, anodized aluminium, and/or the like.

Each of the slots may have a spacing respectively identified as Y₁, Y₂, Y₃, . . . , Yₙ. In one embodiment, the number of slots may be five (i.e., n=5). The length of the slots 330 may be X. In one example, the heights of the 1^{st} slot (Y₁) and 2^{nd} slot (Y₂) may be less than about 47 nm, the height of the 3^{rd} slot (Y₃) and 4^{th} slot (Y₄) may be about 47 nm, and the height of the 5^{th} slot (Y₅) may be about 57 nm (all heights include the thickness of the paddings 330). Those skilled in the art having benefit of the present disclosure may use alternative height and width ranges.

FIG. 4 illustrates a stylized depiction of a cassette that may house a reticle, in accordance with some embodiments herein. In some embodiments, the reticles may be housed in a cassette 410. The cassette 410 may have dimensions of a length (M), width (W), and height (Z). The cassette's dimensions may be slightly larger than the reticles.

The cassette 410 (FIG. 4) may be placed into the slots 320 (FIG. 5) of the reticle carrier unit 210. Automated reticle handlers, which may include an arm that is capable of holding and moving a cassette 410 in or out of the slots 320 may be used to move the reticles. For example, the reticles may be moved from the reticle carrier unit 210 to the process pod 264 (FIG. 2) by moving the cassette 410. Those skilled in the art would appreciate that the drawings provided herein are not drawn to scale.

FIG. 5 illustrates a stylized depiction of an adapter for the reticle carrier unit of FIG. 4, in accordance with some embodiments herein. An adapter 510 may be operatively coupled to the reticle carrier unit 210. In some embodiments, the adapter 510 provides for interfacing the reticle carrier unit 210 with various portions of the automated reticle handling system described herein. In one embodiment, the adapter 510 may be configured such that the reticle carrier unit 210 can interface with the reticle or the process pod 264 (e.g., SMIF pod). In some embodiments, the adapter 510 may be formed from common plastic, polyethelene, stainless steel, anodized aluminium, and/or the like.

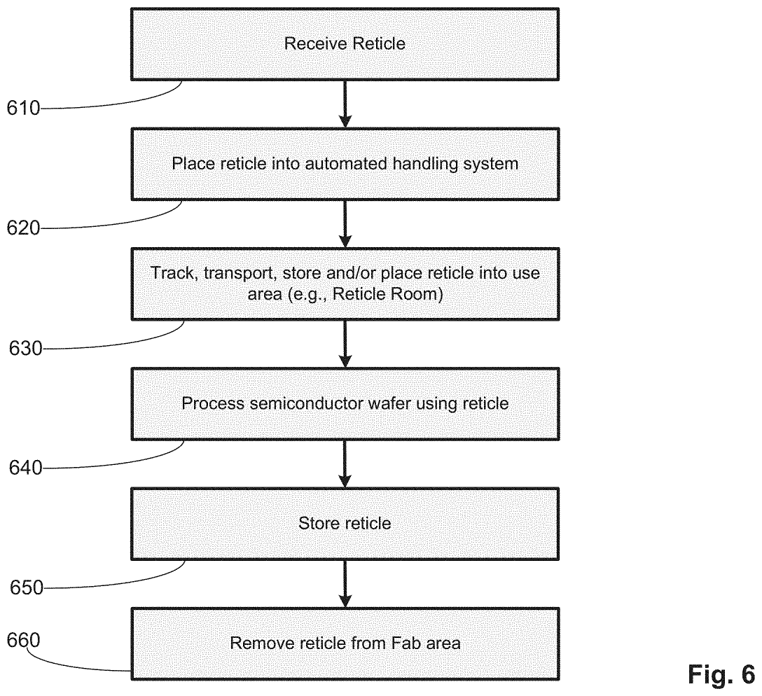

Turning now to FIG. 6, a simplified flowchart depiction of a method in accordance with some embodiments herein, is illustrated. One or more reticles are received (at 610). The reticles may arrive in shipping compartment, such as the reticle carrier unit 210 described above. The reticles may then be placed onto an automated handling system (at 620). The automated handling system may comprise various material handling devices as well as material tracking devices. In some embodiments, an adapter may be affixed onto a reticle carrier unit 210 such that the adapter can be used to hoist the reticle carrier unit 120 onto the automated handling system.

The reticles may then be tracked and transported to a processing area (at 630). In some embodiments, the reticles may be stored prior to being sent to a processing area. A photolithography tool may use one or more reticles in the reticle carrier unit to perform one or more processes (at 640).

Upon being used for processing, one or more reticles may be stored in proximity of the processing area (at 650). One or more semiconductor processing standards may call for storing the used reticles in an area proximate to the processing area for a predetermined time period. Upon expiration of a predetermined time period for storing the reticles, the reticles may be extracted from the processing area for extended storage or for discarding (at 660). In this manner, an automated transporting and tracking of reticles in a fab facility may be provided for processing efficiency.

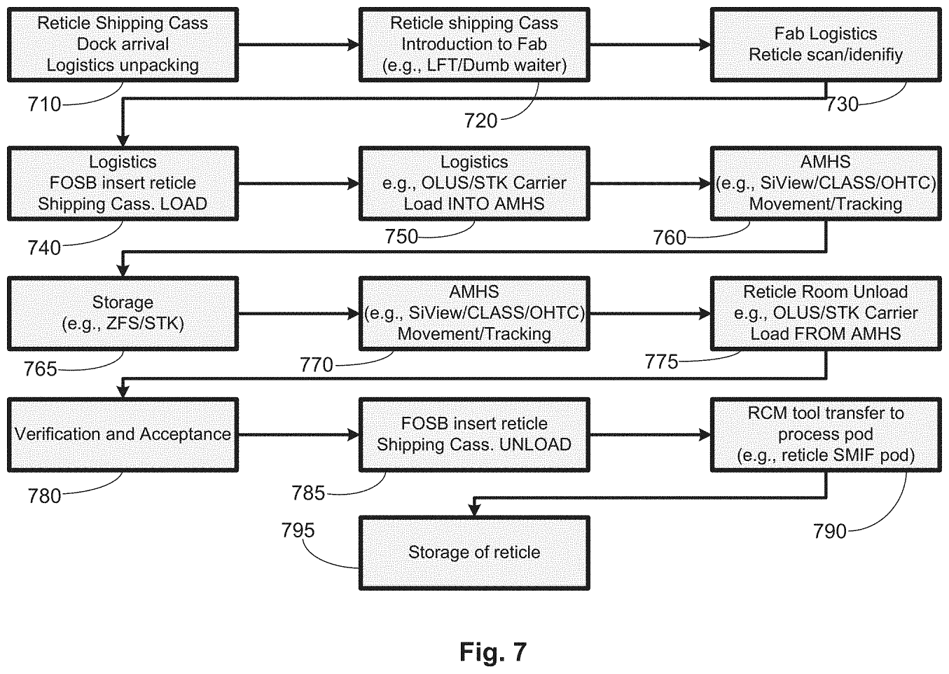

Turning now to FIG. 7, a more detailed flowchart depiction of a method in accordance with some embodiments herein, is illustrated. In one embodiment, a plurality of reticles and cassettes are received at a fab facility (at 710). The reticles and cassettes may arrive at a dock, wherein a logistics team may perform unpacking of the packages containing the reticles.

The reticles and cassettes may then be introduced to the fab facility, e.g., through a FOUP/FOSB multi-floor lifter (LFT) or a dumb waiter (at 720). Subsequently, a reticle tracking process may be performed (at 730). The reticle tracking process may involve barcode scanning, RFID data acquisition, optical scanning, etc., which may be performed in an automated fashion, or alternatively, in a manual fashion by the fab logistics team.

The reticles may be inserted into cassettes and loaded onto a reticle carrier unit (at 740). In some embodiments, an operator load/unload station (OLUS) or a FOUP/FOSB stocker (STK) may be used to load the cassettes containing the reticles onto an automated material handling system (AMHS) (at 750). A movement and tracking control may control the movement of the reticles while tracking the movement (at 760). In some embodiments, the movement and tracking control may be performed by an SiView control system offered by IBM Corp., a CLASS material control system offered by Applied Materials, Inc., an OHTC overhead hoist/conveyor system offered by Muratec USA, Inc., and/or the like.

The reticles may be placed into short-term or long-term storage (at 765). In some embodiments, the reticles may be stored into an automated storage and retrieval system, such as the Zero Footprint Storage (ZFS) system offered by Murata USA, Inc., or Daifuku North America Holding Company, the FOUP/FOSB stocker, and/or the like.

When a particular reticle is to be used for processing, it is moved from short-term or long-term storage by an automated reticle movement system (at 770). In some embodiments, the AMHS exemplified by the SiView, CLASS, OHTC (described above) may be used to move the selected stored reticle to the reticle room.

As the reticle(s) are moved automatically to the reticle room, the reticle(s) may be unloaded (at 775). In some embodiments, the reticles may be unloaded from the automated movement system using OLS or the STK carrier systems (described above). The reticles may be verified and an acceptance procedure may be performed (at 780). The verification and/or the acceptance procedure may be performed automatically, e.g., by a software running on a computer, by a machine learning device, etc. Alternatively, the verification and/or the acceptance procedure may be performed manually by a reticle room technician.

The shipping cassette containing the reticle to be used for processing may be unloaded (at 785). The shipping cassette may be unloaded from the FOSB. The reticle is then transferred to a processing tool (e.g., photolithography tool) for processing. In embodiment, the RCM tool described above may be used to transport the reticle to a processing pod (e.g., the SMIF pod). Upon performing the processing step using the reticle, the reticle may then be stored into the long-term or short-term storage (e.g., ZFS/STK storage described above) (at 795). In this manner, automated movement and tracking of reticles in a fab facility may be performed.

The system 100 described herein may be capable of automated movement of reticles for performing various manufacturing of various products involving various technologies. For example, the system 100 may be used to provide reticles for manufacturing devices of CMOS technology, Flash technology, BiCMOS technology, power devices, memory devices (e.g., DRAM devices), NAND memory devices, and/or various other semiconductor technologies.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
receiving a first reticle;
placing the first reticle onto an automated reticle handling unit;
detecting, automatically, an identifier associated with the first reticle;
receiving a notification to move the first reticle to a processing tool based on the identifier; and
moving, automatically, the reticle to the processing tool capable of performing a processing step using the first reticle.

2. The method of claim 1, further comprising moving, automatically, said first reticle from the processing tool to a reticle storage.

3. The method of claim 1, wherein receiving the first reticle comprises logging the identifier of the first reticle into a first database.

4. The method of claim 1, wherein placing the first reticle onto the automated reticle handling unit comprises:
loading the first reticle into a reticle carrier unit;
placing the reticle carrier unit onto a receptacle of the automated reticle handling unit; and
notifying a fab controller of the loading of the first reticle into the reticle carrier unit and of the location of the reticle carrier unit.

5. The method of claim 4, wherein loading the first reticle into the reticle carrier unit comprises loading the first reticle into a first cassette and loading the first cassette into the reticle carrier unit.

6. The method of claim 1, further comprising:
loading the first reticle into a reticle carrier unit;
loading a second reticle into a second cassette; and
loading the second cassette into the reticle carrier unit.

7. The method of claim 1, wherein moving, automatically, the reticle to the processing tool comprises:
moving, automatically, the first reticle to a reticle clean and maintenance (RCM) device;
placing, by the RCM device, the first reticle onto a process pod; and
moving, by the process pod, the first reticle to the processing tool.

8. An apparatus, comprising:
a reticle carrier unit comprising a first slot for receiving a first cassette having a first reticle;
a reticle identification system capable of detecting an identifier associated with the first reticle;
an automated reticle handling unit capable of automatically receiving the reticle carrier unit and automatically moving the reticle carrier unit to a predetermined location; and
a processing tool for performing a process on the reticle.

9. The apparatus of claim 8, further comprising a reticle receiving area capable of receiving the first cassette and automatically providing the first cassette to the automated reticle handling unit.

10. The apparatus of claim 8, wherein the reticle carrier unit further comprises:
a second slot for receiving a second cassette having loaded within, a second reticle;
a first padding in the first slot and a second padding in the second slot, wherein the first and second padding are capable of stabilizing the first and second cassettes;
an automation system interface capable of providing communications between the reticle carrier unit and the automated reticle handling unit; and
an adapter capable of being operatively coupled onto the reticle carrier unit, wherein the adapter is capable of interfacing with the automated reticle handling unit.

11. The apparatus of claim 8, further comprising an adapter capable of being operatively coupled onto the reticle carrier unit, wherein the adapter is capable of interfacing with the automated reticle handling unit.

12. The apparatus of claim 8, wherein the reticle identification system is capable of at least one of:
detecting a barcode associated with the identifier;
detecting a radio frequency identification signal associated with the identifier; or
detecting an optical identification signal associated with the identifier.

13. The apparatus of claim 8, wherein the automated reticle handling unit comprises:
a controller for controlling an operation of the automated reticle handling unit; and
an automated movement unit for loading, moving, and unloading the reticle carrier unit.

14. The apparatus of claim 8, further comprising:
a distribution system comprising at least one of:
a fab control system for controlling the movement of the reticle carrier unit to a processing tool;
a material control system for controlling the movement of the reticle carrier unit;
a hoist controller capable of controlling the movement of the reticle carrier unit to a storage area;
a reticle storage controller for controlling moving the first reticle to a storage area; and
a storage unit for storing the first reticle.

15. The apparatus of claim 8, wherein the reticle handling device comprises:
a reticle clean and maintenance (RCM) device capable of receiving the first reticle; and
a processing pod capable of moving the first reticle to a processing tool.

16. A system, comprising:
a processing tool;
a process controller operatively coupled to the processing tool, the process controller capable of controlling an operation of the processing tool; and
a reticle carrier system capable of providing a reticle to the processing tool, the reticle carrier system comprising:
a reticle carrier unit comprising a first slot for receiving the first cassette having a first reticle;
a reticle identification system capable of detecting an identifier associated with the first reticle;
an automated reticle handling unit capable of automatically receiving the reticle carrier unit and automatically moving the reticle carrier unit to a predetermined location;
a reticle handling device capable of extracting the first reticle from the reticle carrier unit and providing the first reticle to a processing tool; and
a storage unit for storing the first reticle.

17. The system of claim 16, wherein the reticle carrier unit further comprises:
a second slot for receiving a second cassette having loaded within, a second reticle,
a first padding in the first slot and a second padding in the second slot, wherein the first and second padding are capable of stabilizing the first and second cassettes;
an automation system interface capable of providing communications between the reticle carrier unit and the automated reticle handling unit; and
an adapter capable of being operatively coupled onto the reticle carrier unit, wherein the adapter is capable of interfacing with the automated reticle handling unit and the reticle handling device.

18. The system of claim 16, wherein the automated reticle handling unit comprises:
a controller for controlling an operation of the automated reticle handling unit; and
an automated movement unit for loading, moving, and unloading the reticle carrier unit.

19. The system of claim 16, further comprising:
a distribution system comprising at least one of:
a fab control system for controlling the movement of the reticle carrier unit to the processing tool;
a material control system for controlling the movement of the reticle carrier unit;
a hoist controller capable of controlling the movement of the reticle carrier unit to a storage area; or
a reticle storage controller for controlling moving the first reticle to a storage area; and
a storage unit for storing the first reticle.

20. The system of claim 16, wherein the reticle handling device comprises:
a reticle clean and maintenance (RCM) device capable of receiving the first reticle; and
a processing pod capable of moving the first reticle to a processing tool.
